(19) United States
(12) Patent Application Publication
(10) Pub. No.: US 2008/0182344 A1
(43) Pub. Date: Jul. 31, 2008

(54) Method and system for determining deformations on a substrate

(76) Inventors: Steffen Mueller, Dresden (DE); Alfred Kersch, Putzbrunn (DE); Boris Habets, Dresden (DE); Michael Stadtmueller, Dresden (DE); Thomas Hecht, Dresden (DE)

Correspondence Address: SLATER & MATSIL LLP, 17950 PRESTON ROAD, SUITE 1000, DALLAS, TX, 75252, US

(21) Appl. No.: 11/699,926

(22) Filed: Jan. 30, 2007

(51) Int. Cl. H01L 21/66

(52) U.S. Cl. 438/5; 438/14; 257/E21.521

(57) ABSTRACT

A method and system determines deformations in a substrate in the manufacturing of semiconductor devices. At least one property of vertical deformations of the substrate is measured at a plurality of locations on the substrate. Afterward, an automatic computation of horizontal deformations is determined based on the measured properties of vertical deformations with a model for the deformation behavior of the substrate.

### TECHNICAL FIELD

This invention relates generally to a method and a system for determining deformations on a substrate.

### BACKGROUND

The increasing miniaturization of semiconductor devices, especially in memory chips, the introduction of new materials and the increasing diameters of substrates, such as silicon wafers makes substrate deformations more relevant.

The deformations of the substrates are mainly caused by depositing layers which contains stress. The deformation usually has a horizontal component, i.e. in the plane of the substrate, and a vertical component, i.e., perpendicular to the substrate. The deformations result in unwanted shift of alignment marks that are necessary to assure the accuracy of the lithographic process.

The deformations can affect the whole substrate, i.e., they are global deformations, or the deformations can act locally by variations in the process or the material.

### SUMMARY OF THE INVENTION

Embodiments of the invention are concerned with a method for determining deformations in a substrate in the manufacturing of semiconductor devices.

In one embodiment of at least one property of vertical deformations of the substrate is measured at a plurality of locations on the substrate followed by an automatic computation of horizontal deformations based on the measured properties of vertical deformations with a model for the deformation behavior of the substrate.

Furthermore, embodiments of the invention are concerned with a system with a means for measuring at least one property of vertical deformations at a plurality of locations on a substrate used in the manufacturing of semiconductor devices and means for the automatic computation of horizontal deformations based on the measured properties of vertical deformations with a model for the deformation behavior of the substrate.

### BRIEF DESCRIPTION OF THE DRAWINGS

Other preferred embodiments and advantages of the invention become apparent upon reading of the detailed description of the invention, and the appended claims provided below, and upon reference to the drawings.

FIG. 1 shows a graph with a typical vertical deformation of a silicon wafer;

FIG. 2A shows a graph with an exemplary deviation of the deformation from an ideal ellipsoid;

FIG. 2B shows a graph with an exemplary deviation of the deformation from an ideal paraboloid;

FIG. 3 shows measured vertical deformations of an exemplary substrate;

FIG. 4 shows the computed stress distribution in the substrate according to FIG. 3;

FIG. 5 shows the computed horizontal deformation for the substrate depicted in FIG. 4;

FIG. 6 shows as the result of the computation the local horizontal shifts on the substrate according to FIG. 5;

FIG. 7 shows a flow chart of the computation for an embodiment of the method;

FIG. 8 shows an embodiment of a first process flow using an embodiment of the present invention;

FIG. 9 shows an embodiment of a second process flow using an embodiment of the present invention;

FIG. 10 shows an embodiment of a third process flow using an embodiment of the present invention; and

FIG. 11 shows an embodiment of a fourth process flow using an embodiment of the present invention.

### DETAILED DESCRIPTION OF ILLUSTRATIVE EMBODIMENTS

In the following an embodiment of the method according to the invention and an application of the system according to the invention are described in the context of a silicon wafer in the production of a DRAM memory chip. This example is non-limiting since also NROM, microprocessors and other integrated circuits might be manufactured from silicon substrates. Furthermore, substrates as mentioned before are also used in the manufacturing of microelectromechanical systems (MEMS).

It will be understood by a person skilled in the art that the exemplary description also applies to other substrates used in the manufacturing of semiconductor devices. Examples for another substrate are III-V substrates used in the manufacturing of optoelectronic devices or SOI wafers.

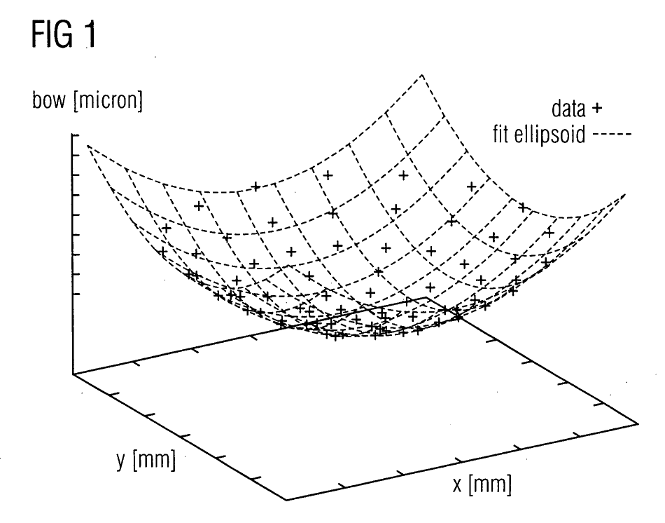

In FIG. 1 the vertical deformation w of a silicon wafer is shown. Mathematically, it is given by a function w(x,y). In the typical application this deformation results from a stress layer with a thickness δ (as will be described below) with nearly homogeneous stress which leads to an approximately parabolic or elliptic function with some deviation from such a regular shape, the bow residual:

w(x,y)=Ax²+By²+Cxy+w^{(bow residual)}(x,y) (1)

The absolute values of the deformation (i.e. here the vertical displacement), measured in μm on the z-axis, are increasingly positive towards the rim of the substrate and increasingly negative towards the center. The maximum absolute positive deformation is about 300 μm, the maximum absolute negative deformation is about 100 μm.

The vertical deformation displacement of the silicon wafer, i.e., the substrate can be measured with well known optical scanning methods. One other method is the capacitive method where the capacitance between a measurement spot and the wafer in closest distance is measured.

The measurement of the vertical displacement is only one preferred embodiment of the measurement of at least one property of a vertical deformation of a substrate.

Alternatively or in connection to the vertical displacement, the local curvature can be measured as a different property of the vertical deformation. This would imply a measurement of the second derivatives of the vertical deformation function. In another embodiment the local variations of atomic distances and/or local variations of atomic bonding parameters can be measured alternatively or in connection with other measurements. Measurements at the atomic level could be obtained from x-ray, electron beam or Raman scattering, resulting in effect in the measurement of local displacements.

In the following embodiments, the use of a measured displacement is described if not mentioned otherwise.

To obtain reasonable results the number of vertical deformation measurements need to be sufficiently large. Usually more than 100 measurements will be desirable for a wafer with 300 mm diameter. The accuracy of the vertical measurements should be preferably better than 1 μm.

To obtain reasonable results for horizontal displacement caused by processes it is furthermore preferable to measure the vertical deformation of the incoming wafer before the stress creating processes are applied and subtract this incoming deformation from the final deformation.

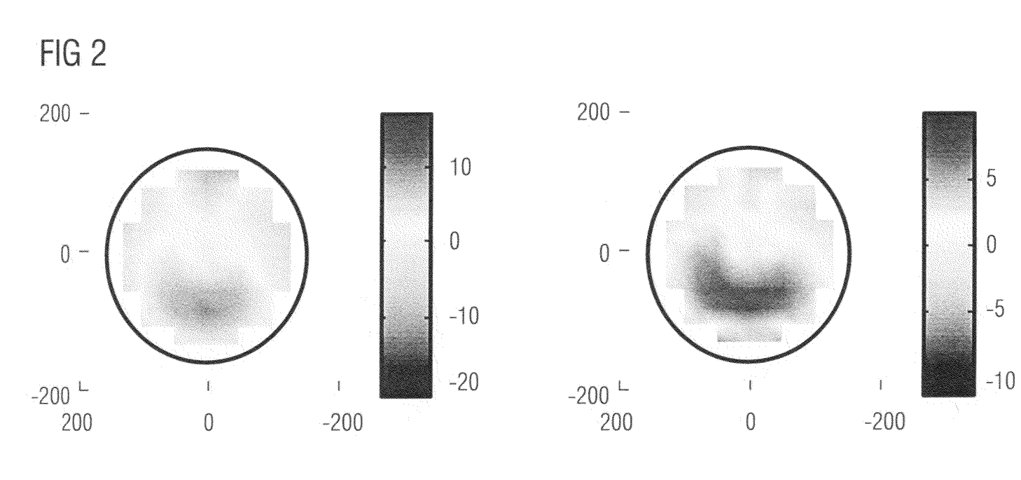

In FIGS. 2A and 2B typical deviations of the deformation from an ideal ellipsoid (FIG. 2A) and an paraboloid (FIG. 2B) are depicted. The deviations are measured in μm.

From the vertical deformation measurements the two dimensional geometrical stress distribution σ^{(layer)}(x,y) of the layer can be computed.

Fundamental to the method is the expression for the total elastic energy F of a wafer with surface Ω, thickness of d and a layer on the surface of the wafer with a thickness δ containing fixed film stress components σₓₓ^{(layer)}, σ_{yy}^{(layer)},σ_{xy}^{(layer)}. In the standard application of the method, the stress will be assumed to be biaxial and without shear stress i.e. σ^{(layer)}=σₓₓ^{(layer)}=σ_{yy}^{(layer)} and σ_{xy}^{(layer)}=0. x and y are oriented in the <100> direction of the wafer. σₓₓ, σ_{yy}, σ_{xy} and eₓₓ, e_{yy}, e_{xy} are stress and strain of the wafer substrate caused by the layer stress.

$$F = \frac{1}{2} {\int }_{0}^{d} {\int }_{Ω}^{ } [ {σ}_{xx} {e}_{xx} + {σ}_{yy} {e}_{yy} + {σ}_{xy} {e}_{xy} ] d Ω d z + {\int }_{d}^{d + ϑ} {\int }_{Ω}^{ } [ {σ}_{xx}^{( layer )} {e}_{xx} + {σ}_{yy}^{( layer )} {e}_{yy} + {σ}_{xy}^{( layer )} {e}_{xy} ] d Ω d z \qquad ( 2 )$$

Stress σᵢⱼ and strain σᵢⱼ of the wafer substrate are related by a stress-strain relation for cubic crystal symmetry:

$$( \begin{matrix}{σ}_{xx} \\ {σ}_{yy} \\ {σ}_{zz} \\ {σ}_{xy} \\ {σ}_{xz} \\ {σ}_{yz}\end{matrix} ) = ( \begin{matrix}{c}_{11} & {c}_{12} & {c}_{12} & 0 & 0 & 0 \\ {c}_{12} & {c}_{11} & {c}_{12} & 0 & 0 & 0 \\ {c}_{12} & {c}_{12} & {c}_{11} & 0 & 0 & 0 \\ 0 & 0 & 0 & {c}_{44} & 0 & 0 \\ 0 & 0 & 0 & 0 & {c}_{44} & 0 \\ 0 & 0 & 0 & 0 & 0 & {c}_{44}\end{matrix} ) ( \begin{matrix}{ɛ}_{xx} \\ {ɛ}_{yy} \\ {ɛ}_{zz} \\ {ɛ}_{xy} \\ {ɛ}_{xz} \\ {ɛ}_{yz}\end{matrix} ) \qquad ( 3 )$$

for silicon c₁₁=166 GPa, c₁₂=63.9 GPa, c₄₄=79.6 GPa

For other substrate crystal symmetries similar relations hold. For the cubic symmetric silicon wafer the total energy is:

$${F}^{( bow )} = \frac{1}{2} {\int }_{0}^{d} {\int }_{Ω}^{ } [ ( {c}_{11} - \frac{{c}_{12}^{2}}{{c}_{11}} ) ( {e}_{xx}^{2} + {e}_{yy}^{2} ) + 2 ( {c}_{12} - \frac{{c}_{12}^{2}}{{c}_{11}} ) {e}_{xx} {e}_{yy} + {c}_{44} {e}_{xy}^{2} ] d Ω d z + {\int }_{d}^{d + ϑ} {\int }_{Ω}^{ } [ {σ}_{xx}^{( layer )} {e}_{xx} + {σ}_{yy}^{( layer )} {e}_{yy} + {σ}_{xy}^{( layer )} {e}_{xy} ] d Ω d z \qquad ( 4 )$$

A wafer which is not constrained to the plane by a clamping or chucking force will respond to the layer stress σ^{(layer)} with a vertical wafer deformation (wafer bow) w(x,y). The Kirchhoff approximation (valid for deformation smaller than wafer thickness) relates this vertical deformation to the horizontal strain:

$${e}_{xx} = - ( z - {z}_{( neutral )} ) \frac{{\partial }^{2} w}{\partial {x}^{2}} \\ {e}_{yy} = - ( z - {z}_{( neutral )} ) \frac{{\partial }^{2} w}{\partial {y}^{2}} \\ {e}_{xy} = - ( z - {z}_{( neutral )} ) \frac{{\partial }^{2} w}{\partial x \partial y} \qquad ( 5 )$$

z₍ₙₑᵤₜᵣₐₗ₎=d/3 is the position of the neutral plane. After substitution of the strain and integration over the wafer thickness, the total energy becomes:

$${F}^{( bow )} = \frac{{d}^{3}}{18} {\int }_{Ω}^{ } [ ( {c}_{11} - \frac{{c}_{12}^{2}}{{c}_{11}} ) [ {( \frac{{\partial }^{2} w}{\partial {x}^{2}} )}^{2} + {( \frac{{\partial }^{2} w}{\partial {y}^{2}} )}^{2} ] + 2 ( {c}_{12} - \frac{{c}_{12}^{2}}{{c}_{11}} ) [ \frac{{\partial }^{2} w}{\partial {x}^{2}} \frac{{\partial }^{2} w}{\partial {y}^{2}} ] + {{c}_{44} ( \frac{{\partial }^{2} w}{\partial x \partial y} )}^{2} ] - \frac{2 d ϑ}{3} {\int }_{Ω}^{ } [ {σ}_{xx}^{( layer )} \frac{{\partial }^{2} w}{\partial {x}^{2}} + {σ}_{yy}^{( layer )} \frac{{\partial }^{2} w}{\partial {y}^{2}} + {σ}_{xy}^{( layer )} \frac{{\partial }^{2} w}{\partial x \partial y} ] \qquad ( 6 )$$

From this expression, the wafer deformation w(x,y) can be calculated from the layer stress by solving the corresponding plane equation or by numerical solution with known methods like Finite Element methods (FEM), Finite Difference Methods (FDM) or Boundary Element Methods (BEM).

The same wafer, which is forced in the plane by a clamping or chucking force will respond to the same layer stress σ^{(layer)} with a horizontal deformation u(x,y) and v(x,y) (wafer distortion in x and y direction). The horizontal deformation is related to the horizontal strain by the defining relations:

$${e}_{xx} = \frac{\partial u}{\partial x} {e}_{yy} = \frac{\partial v}{\partial y} {e}_{xy} = \frac{1}{2} ( \frac{\partial u}{\partial y} + \frac{\partial v}{\partial x} ) \qquad ( 7 )$$

The components of the strain tensor can be substituted by the horizontal displacement such that:

$${F}^{( distortion )} = \frac{1}{2} {\int }_{0}^{d} {\int }_{Ω}^{ } [ ( {c}_{11} - \frac{{c}_{12}^{2}}{{c}_{11}} ) [ {( \frac{\partial u}{\partial x} )}^{2} + {( \frac{\partial v}{\partial y} )}^{2} ] + 2 ( {c}_{12} - \frac{{c}_{12}^{2}}{{c}_{11}} ) \frac{\partial u}{\partial x} \frac{\partial v}{\partial y} + {c}_{44} \frac{1}{4} ( \frac{\partial u}{\partial y} + \frac{\partial v}{\partial x} ) ] d Ω d z + {\int }_{d}^{d + ϑ} {\int }_{Ω}^{ } [ {σ}_{xx}^{( layer )} \frac{\partial u}{\partial x} + {σ}_{yy}^{( layer )} \frac{\partial v}{\partial y} + {σ}_{xy}^{( layer )} \frac{1}{2} ( \frac{\partial u}{\partial y} + \frac{\partial v}{\partial x} ) ] d Ω d z \qquad ( 8 )$$

From this expression the wafer distortion u(x,y) and v(x,y) can be calculated from the three layer stress components by solving the corresponding differential equations or by numerical solution with, e.g., Finite Element methods (FEM).

We first assume σ^{(layer)}=σₓₓ^{(layer)}=σ_{yy}^{(layer)} and σ_{xy}^{(layer)}=0. The calculation of the layer stress distribution σ^{(layer)}(x,y) and the wafer distortion u(x,y) and v(x,y) from the vertical deformation w(x,y) is realized by the introduction of a functional basis, {σₖ^{(basis)}(x,y),kεbasis} for arbitrary layer stress distributions which allows the approximate representation as:

$$σ ( x , y ) \approx {\sum }_{k ∈ basis} {a}_{k} {σ}_{k}^{( basis )} ( x , y ) , {a}_{k} fit parameter \qquad ( 9 )$$

An example for such a basis is given by a set of Gaussian functions distributed over the wafer with width parameter α:

{σₖ^{(basis)}(x,y)=exp(−α(x/R−ξₖ)²)exp(−α(y/R−ψ_{y})|(ξₖ,ψₖ)regular grid on wafer} (10)

Many other basis sets are possible. The choice depends on the desired accuracy of the calculation. Now this stress basis function will be fitted to the measured vertical wafer deformation by the use of a least square fit. The first step is to calculate the corresponding vertical deformation basis functions {wₖ^{(basis)}(x,y),kεbasis} and horizontal distortion basis functions {uₖ^{(basis)}(x,y), kεbasis} and {vₖ^{(basis)}(x,y),kεbasis} by solving the equations (6) and (8) for the stress basis functions. This calculation has to be done only once. The resulting set of vertical and horizontal basis deformations corresponding to the stress basis functions can then be utilized in purely algebraic calculations.

Let {wᵢ|measurement in (xᵢ,yᵢ) with error βᵢ} be the set of measurements of the vertical deformation. The vertical deformation basis functions wₖ^{(basis)}(x,y) can be fitted to the measurements wᵢ by minimizing the expression:

$${χ}^{2} = {\sum }_{i ∈ measurements} {[ \frac{{w}_{i} - {\sum }_{k} {a}_{k} {w}_{k}^{( basis )} ( {x}_{i} , {y}_{i} )}{{β}_{i}} ]}^{2} \qquad ( 11 )$$

The explicit solution for the minimum of χ² is:

$${a}_{k} = {\sum }_{m} {( {\sum }_{i} \frac{{w}_{m}^{( basis )} ( {x}_{i} , {y}_{i} ) {w}_{k}^{( basis )} ( {x}_{i} , {y}_{i} )}{{β}_{i}^{2}} )}^{- 1} ( {\sum }_{i} \frac{{w}_{i} {w}_{m}^{( basis )} ( {x}_{i} , {y}_{i} )}{{β}_{i}^{2}} ) \qquad ( 12 )$$

Using the calculated aₖ the corresponding layer stress distribution σ^{(layer)}(x,y) can be computed as:

$${σ}^{( layer )} ( x , y ) = {\sum }_{k ∈ basis} {a}_{k} {σ}_{k}^{( basis )} ( x , y ) \qquad ( 13 )$$

Because the layer stress causing the vertical and the horizontal deformation is the same, the horizontal deformation is simply:

$$u ( x , y ) = {\sum }_{k ∈ basis} {a}_{k} {u}_{k}^{( basis )} ( x , y ) \\ v ( x , y ) = {\sum }_{k ∈ basis} {a}_{k} {v}_{k}^{( basis )} ( x , y ) \qquad ( 14 )$$

In case the local curvature of a substrate is measured the stress function has to take the second derivatives into account, so that the above given equations have to be modified. In this version of the method the second derivative of w(x,y) can be related to substrate strain (equation (5)), then to substrate stress and finally to layer stress. Subsequently the layer stress distribution can be fitted to the stress basis functions (equation 13) and the horizontal deformation is finally obtained (equation 14).

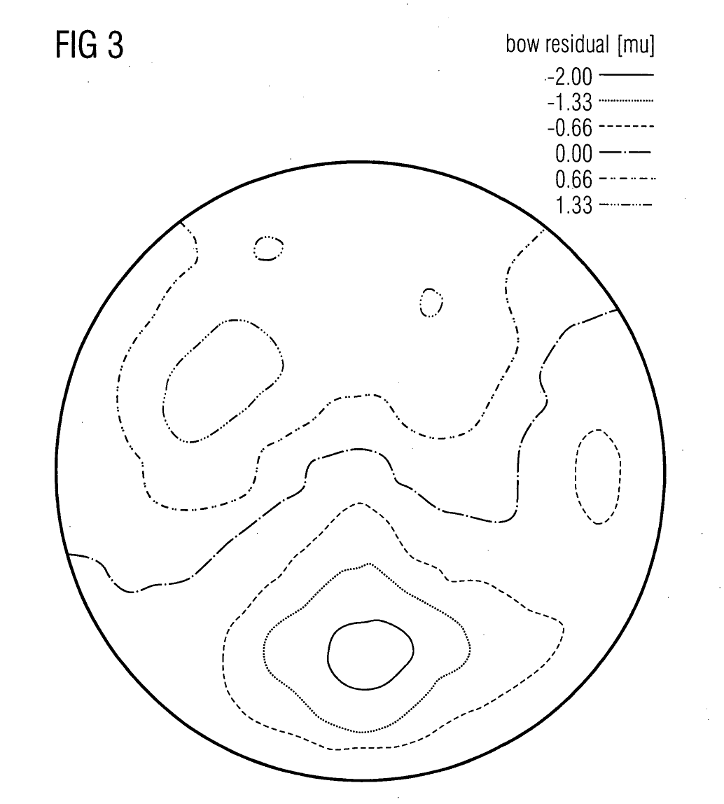

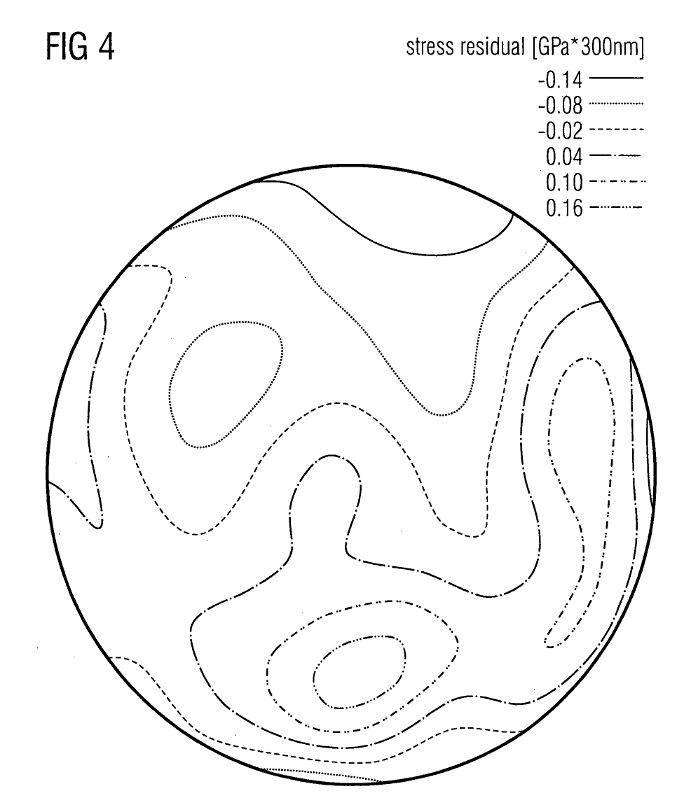

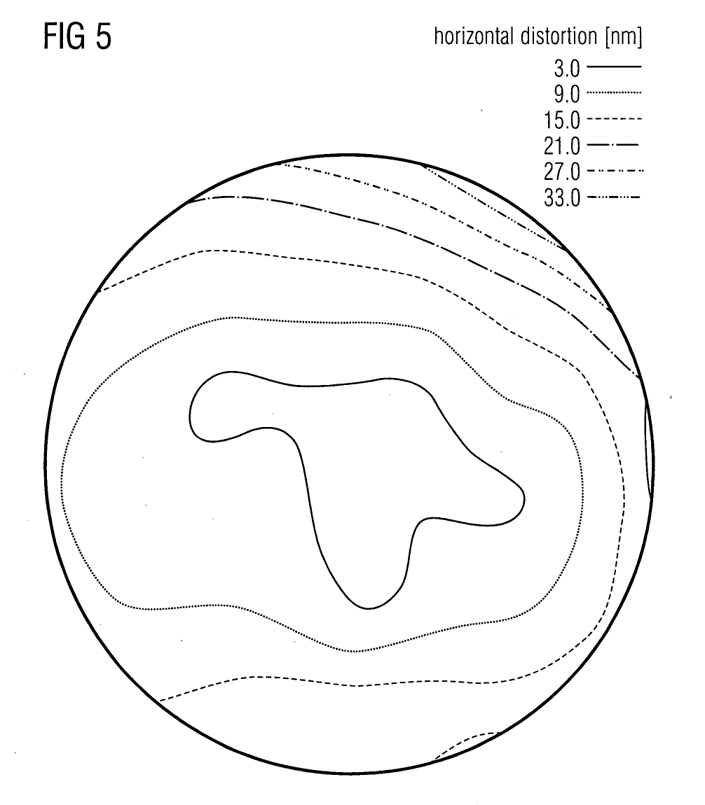

In FIG. 3 the measured vertical deformation w is depicted. The contour lines give the bow residuals in μm. Using the method described above, the layer stress distribution σ^{(layer)}(x,y) in FIG. 4 can be computed. FIG. 4 shows the stress residuals (i.e., the stress minus the constant stress) (the contour lines in FIG. 4 are the stress residuals). The units are GigaPascal multiplied with a thickness of 300 nm describing line tensions. The corresponding horizontal deformation related to the same stress distribution in FIG. 4 is shown in FIG. 5. The horizontal deformation is a measure of how much, e.g., alignment marks are shifted on this particular wafer.

To this calculated horizontal deformation a global correction is applied consisting of a linear scaling in x and y, a rotation and a linear translation such that the least square sum of the deformation residuals is minimal. This global correction is necessary to compare the calculated residuals with alignment data from lithography because the alignment residual data is typically subjected to such linear transformation. Physically the linear transformation corresponds to a subtraction of a homogeneous stress component from the true stress or equivalently to the subtraction of a parabolic deformation from the true deformation. The minimal deformation residual corresponds to the inhomogeneous part of the stress or the bow residual of the vertical deformation.

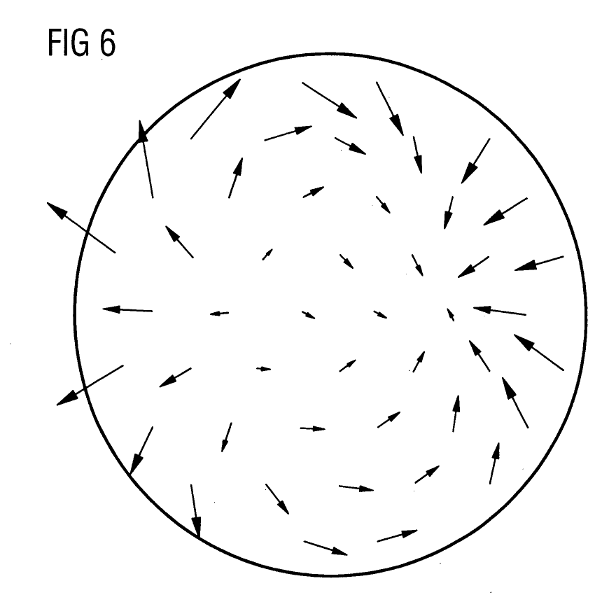

In FIG. 6 the local horizontal deformations are indicated by arrows. Knowing these localized deformations, localized corrections can be applied, e.g., to correct for the shifted alignment markers. As will be described below, the exposure fields of the exposure grid of the lithography system can be, e.g., translated and/or rotated to adjust for these deformations.

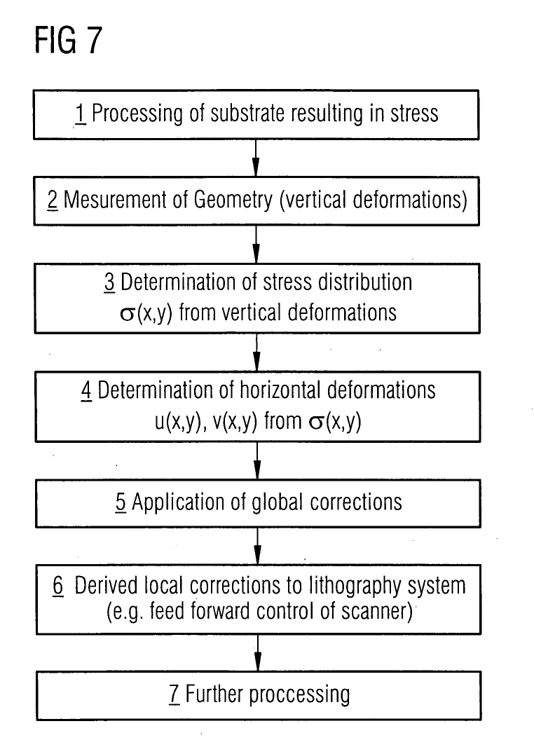

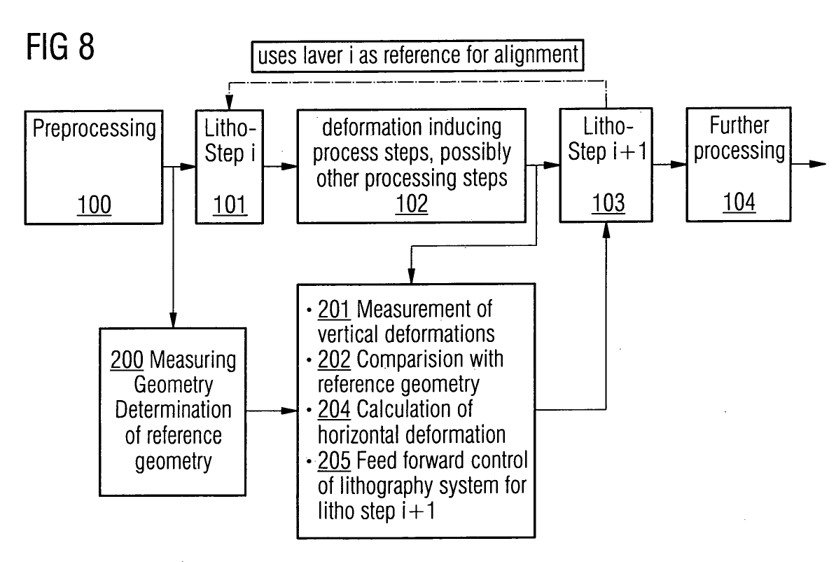

In FIG. 7 the overall process flow for the described embodiment is summarized. In process step 1 the substrate, here a silicon wafer is subjected to processing steps like etching and/or deposition of layers resulting in an internal stress in the wafer. In FIGS. 8 to 11 it will be shown that this processing can take place between two or more lithography steps.

As described in connection with FIG. 3 the vertical deformation w(x,y) is determined in process step 2.

Using, e.g., the equations described above the stress distribution σ^{(layer)}(x,y) is derived from the measured data in process step 3. In process step 4 the stress distribution σ^{(layer)}(x,y) provides the input to e.g. a finite element program to obtain horizontal deformations u(x,y) and v(x,y). In a preferred embodiment a global correction is applied to the computed horizontal deformations in process step 5. Furthermore, in a preferred embodiment the corrected horizontal deformations are used in a feed forward control of a lithography system, e.g., a scanner, in process step 6.

In the following two embodiments of a data transmissions to the lithography system are described.

In a first variant illumination parameters are passed on the lithography system, i.e., the calculated correction parameters are used to correct the individual illumination fields (e.g., 6 parameter model). The correction can be a translation, a rotation and/or a sizing in x and/or y direction.

In the second variant model parameters are passed on to the lithography system. This means that model parameters for the illumination model (e.g., high-order alignment model, 6-parameter model etc.) installed on the scanner are passed on.

Both feed forward controls, especially the described two variants can be applied for individual wafers, i.e., the corrections are applied to each wafer according to the individually measured wafers. Alternatively, the control of the lithography system can be applied to a group of wafers, i.e., measurement of one wafer is taken as a representative to a group of wafers. This is justified in cases where the pre-processing of wafers is so similar, that the vertical deformation is similar in all wafers of the group.

In another preferred embodiment the stress calculation of the stress in the substrate could be based on Airy's stress function. The Airy function is a potential function underlying 2 dimensional stress problems and can be constructed by integrating local curvature. Stress and displacement can be calculated from derivatives. Mathematical details can be found in the literature.

An embodiment of the present invention is also applicable to a substrate, e.g., a silicon wafer, which has been coated on the backside compensating for the global deformation in the substrate. This backside coating could be a process induced coating or a deliberately applied layer on the backside.

An example for such a backside coating is the application to a substrate of a structured side (front side) that contains tensile stress which is compensated for by a backside layer also containing tensile stress. The resulting vertical deformations would only occur at localized positions due to stress inhomogenities so that the vertical deformations would not be completely cancelled. In such a case the horizontal deformation could be large (approximately twice as large as without backside coating), the vertical deformations would be comparatively small.

The embodiments of the present invention can also be used in this situation.

The vertical deformation would be measured and the stress distribution σ^{(layer)}(x,y) would be calculated as described above for the case without a backside coating. But the stress distribution with backside coating would be the stress distribution of the front side minus the stress distribution on the backside σ^{(layer)}(x,y)−R.

Based on the layer stress distribution σ^{(layer)}(x,y) the horizontal deformations are calculated. The calculated horizontal deformation is σ^{(layer)}(x,y)−R, the real would be σ^{(layer)}(x,y)+R.

The difference would be a constant stress of 2R which is globally correctable. This global correction would be applied. The residuals of the extracted stress distribution are the same.

In FIGS. 8 to 11, four different process flows are described which use embodiments of the present invention.

Common to all process flows is that between two lithography steps 101 and 103, as shown in FIG. 8, the substrate is processed (process step 102) so that stress is introduced. This stress results in vertical and horizontal deformation. The different process flows show different ways in dealing with this situation.

In FIG. 8 the substrate comes from some preprocessing 100 to a first lithography step 101. To establish a base line for later deformation of the substrate, the geometry, e.g., the vertical deformation is measured (process step 200).

After the substrate is processed 102 (e.g., by etching, deposition or heat treatment), deformation is present in the substrate. The problem would be that the horizontal deformation of the substrate has shifted the alignment marks from the first lithography step 101, so that the second lithography step 103 would be miss-aligned in reference to lithography step 101. In the embodiment of FIG. 8, both lithography steps are critical, i.e., the relative alignment of the manufactured layers is important.

Usually a lithography step uses the pattern introduced by a previous lithography step as a reference due to alignment marks. The lithography steps 101 and 103 comprise an alignment, the illumination and development of the substrate. Optionally an overlay measurement, a CD-measurement or a rework step can be part of the lithography steps.

To allow an improved alignment, an embodiment of the method according to the present invention is used. In process steps 201 to 204 horizontal deformations are determined and correction factors are used in a feed forward control of the second lithography step 103. The features of the method have been described above so reference can be made to the above description.

In addition to the previously described method, a comparison (process step 202) is made with a reference geometry obtained in process step 200. The comparison allows the computation of a difference which increases accuracy of the determination of the horizontal deformations.

The passing on of the deformation data to the second lithography step 103 can be facilitated with one of the variants described in connection with FIG. 7.

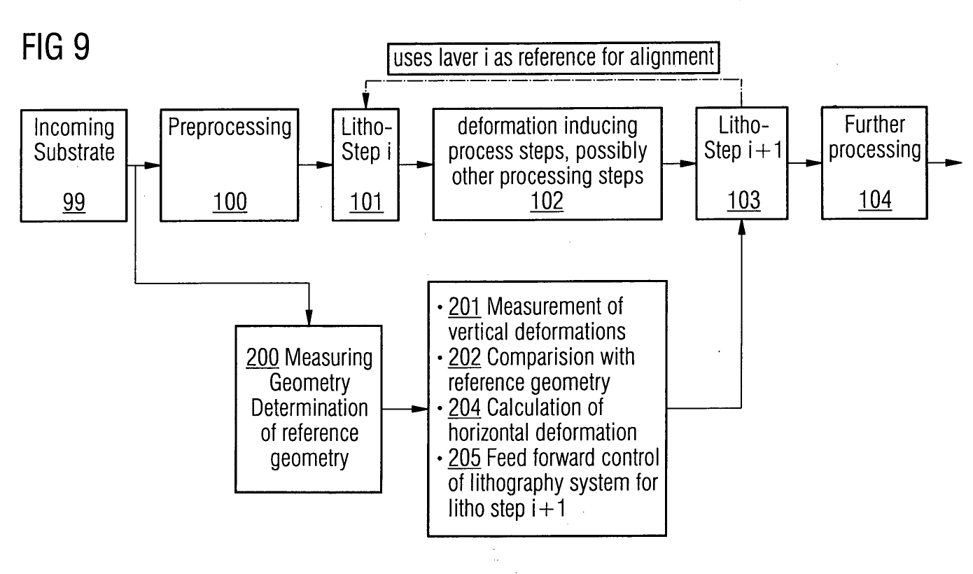

In FIG. 9 a variation of the process flow described in FIG. 8 is described to that reference is made to that description. The difference compared with the embodiment of FIG. 8 is that the reference geometry obtained in process step 200 is not directly measured before the first lithography step 101, but after some other process step 99 but before the pre-processing step 100. The remaining process steps conform to the process flow in FIG. 8.

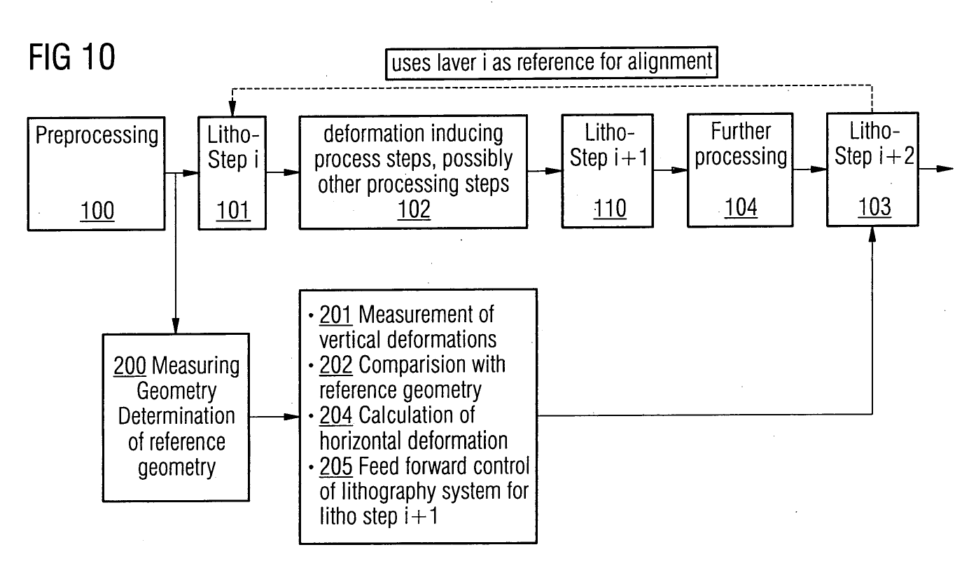

In FIG. 10 another variant of FIG. 8 is described so that reference is made to the above description.

In addition to the two critical lithography steps 101 and 103, an additional uncritical lithography step 110 is introduced after the deformation inducing step 102. Uncritical means that the alignment of the manufactured pattern to previous layers is not as important.

After the uncritical lithographic step 110 the substrate is further processed and then subjected to the next lithography step 103. Since the relative alignment between the critical lithography steps 101 and 103 is important, the feed forward control of the lithography system is applied to the second critical lithography 103. The measurement of the reference geometry is here taken before the first lithography step 101. Alternatively this measurement could be taken at a previous process step, as indicated in FIG. 9.

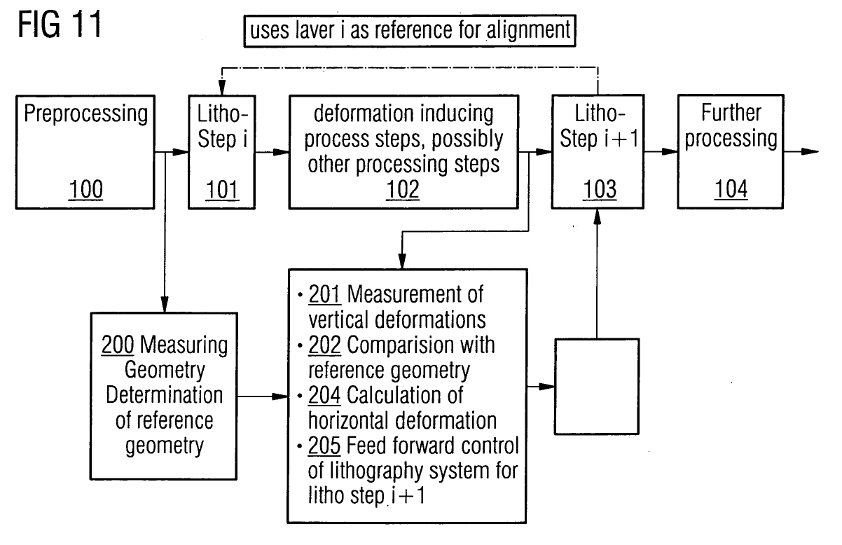

In FIG. 11 another embodiment based on the process flow described in connection with FIG. 8 is depicted. Reference is made to the relevant description of FIG. 8. The difference of the embodiment shown in FIG. 11 is that the feed forward process is modified. The data on the horizontal deformation which is determined in process step 205 and transmitted to the lithography system is classified into different classes according to the deformation. This means that substrates having similar deformations, as predefined in the rules for the classes, will be subjected to certain predefined parameters (i.e., for the illumination model) for the lithography step 103. This binning allows a simpler processing since the lithography step 103 does not have to be adjusted to each substrate individually.

If the deformations are found to be so severe that further processing does not seem technically feasible or economical, the particular substrate might be removed from the process flow, saving valuable processing time later on.

This discarding of substrates based on the calculated deformation data might also be used in connection with one of the other embodiments described, i.e., the classification as shown in FIG. 11 is not necessary for that.

The embodiments of the present invention have been described in the context of a feed forward control of a lithography system. The correction factors for the horizontal deformation can be used for other process steps in the manufacturing of semiconductor devices. In other preferred embodiments, the correction factors can be applied to, e.g., etching systems or deposition equipment, e.g., for the deposition of hardmasks. These process steps also depend on data representing the surface of the substrate, e.g., the horizontal deformation of the substrate before the, e.g., etching or deposition is applied.

The embodiments of the present invention have been described in connection with a model for the deformation behavior based on first principles, i.e., stress mechanical relationships.

The embodiments of the present invention are not limited to these types of models. The deformation behavior can also be described by empirical models, which can, e.g., be gained by performing a number of experiments. The result of the experiments could then be put into the form of a statistical or parametric model. The empirical models of this time can model the deformation behavior of the substrate within the boundaries of the experiment. It might be possible to extrapolate results based on the empirical model. One way of obtaining an empirical model is an neural net method being trained on the experimental results of the deformation behavior. In principle other methods of statistical model building can be used.

In embodiments of the invention the deformation of the substrate is measured and correction factors for the horizontal deformation can be derived. It should be noted that the deformation and the correction factors can be derived for the complete substrate (e.g., a silicon layer with a plurality of layers on the substrate) or in an incremental way, i.e., for individual layers on the substrate. The deformations of subsequent layers can be expressed in a relative way, i.e., the relative deformation from layer to layer can be determined and respective correction factors can be computed. Alternatively, the deformation can be calculated relative to a reference substrate having a predefined stress, including the case that the reference substrate has no stress.

What is claimed is:

1. A method for determining deformations in a substrate in the manufacturing of semiconductor devices, the method comprising:
measuring at least one property of vertical deformations of the substrate at a plurality of locations on the substrate; and
then, automatically computing horizontal deformations based on the measured properties of vertical deformations with a model for the deformation behavior of the substrate.

2. The method according to claim 1, wherein the at least one property of vertical deformations is at least one of the groups of vertical displacement, local curvature, local variations of atomic distances and local variations of atomic bonding parameters.

3. The method according to claim 1, wherein at least one property of the vertical deformation is measured by an optical method.

4. The method according to claim 1, wherein automatically computing horizontal deformations comprises using a material stress model.

5. The method according to claim 4, wherein a stress distribution in the substrate is computed from the vertical deformation data by solving a parameter optimization problem, the parameters being part of the model.

6. The method according to claim 1, wherein automatically computing horizontal deformations comprises using an empirical model.

7. The method according to claim 1, wherein automatically computing horizontal deformations comprises using a model derived from a parameter fitting method.

8. The method according to claim 1, wherein the horizontal deformations are computed from the computed stress distribution in the substrate.

9. The method according to claim 1, wherein the horizontal deformations are computed by one method from the group consisting of a finite-element method, a finite-difference method, and a boundary element method.

10. The method according to claim 1, further comprising determining at least one correction factor for the substrate.

11. The method according to claim 1, wherein further comprising determines at least one correction factor at least at one stage of the processing of the substrate.

12. The method according to claim 1, further comprising generating correction factors for a processing equipment processing the substrate.

13. The method according to claim 1, wherein correction factors are used in a feed forward control of a processing system for the substrate.

14. The method according to claim 11, wherein the at least one correction factor is applied to at least one process step selected from the group consisting of lithography, etching, and deposition.

15. The method according to claim 11, wherein the at least one correction factor is applied individually to a measured substrate individually.

16. The method according to claim 11, wherein the at least one correction factor is applied to groups of substrates.

17. The method according to claim 1, wherein at least one correction factor is used in the controlling of a lithographic system.

18. The method according to claim 17, wherein the at least one correction factor is computed for individual exposure fields of the lithographic system.

19. The method according to claim 17, wherein the correction factors are transformed into model parameters for alignment models in the lithographic system.

20. The method according to claim 1, wherein the calculated horizontal deformation is used to classify substrates into at least two classes so that the further processing of the substrates depends on the classification.

21. The method according to claim 20, wherein the classification is used for at least one of the groups of selecting parameters for a lithography step and/or discarding of unsuitable substrates.

22. The method according to claim 1, further comprising performing a reference measurement of at least one property of vertical deformations of the substrate before a process step introducing a deformation in the substrate, the reference measurement being used to calculate a difference to the measurement after the deformation inducing process step.

23. The method according to claim 1, wherein at least 50 measurements of the at least one property of the vertical deformation are performed per wafer.

24. The method according to claim 1, wherein the accuracy of at least one property of the vertical deformation is better than 5 μm.

25. The method according to claim 1, wherein the substrate is a substrate selected from the group consisting of a silicon wafer, a SOI-wafer, and a III-V material wafer.

26. The method according to claim 1, wherein the semiconductor device comprises at least one device selected from the group consisting of a memory chip, microelectromechanical system and microprocessor.

27. A system for determining the horizontal deformation of a substrate, the system comprising:
means for measuring at least one property of vertical deformations at a plurality of locations on a substrate used in the manufacturing of semiconductor devices; and
means for the automatic computation of horizontal deformations based on the measured properties of vertical deformations with a model for the deformation behavior of the substrate.
